(19) United States
(12) Patent Application Publication
(10) Pub. No.: US 2025/0320628 A1
(43) Pub. Date: Oct. 16, 2025

(54) EPI ISOLATION PLATE AND PARALLEL BLOCK PURGE FLOW TUNING FOR GROWTH RATE AND UNIFORMITY

(71) Applicant: Applied Materials, Inc., Santa Clara, CA (US)

(72) Inventors: Zhepeng CONG, San Jose, CA (US); Tao SHENG, Santa Clara, CA (US); Errol Antonio C. SANCHEZ, Tracy, CA (US); Mike RICE, Pleasanton, CA (US); Nimrod SMITH, Cupertino, CA (US); Ashur J. ATANOS, San Jose, CA (US)

(21) Appl. No.: 19/247,322

(22) Filed: Jun. 24, 2025

Related U.S. Application Data
(62) Division of application No. 18/140,207, filed on Apr. 27, 2023.
(60) Provisional application No. 63/441,400, filed on Jan. 26, 2023.

(51) Int. Cl. C30B 25/14; C23C 16/44; C23C 16/455; C23C 16/46; C30B 25/10

(52) U.S. Cl. CPC C30B 25/14; C23C 16/4408; C23C 16/45502; C23C 16/46; C30B 25/10

(57) ABSTRACT

A method and apparatus for processing substrates suitable for use in semiconductor manufacturing. The method includes heating a substrate positioned on a substrate support. The method includes flowing a purge gas over an isolation plate disposed above the substrate, the flowing the purge gas including diverting a portion of the purge gas below the isolation plate through a plurality of perforations in the isolation plate. The method includes flowing one or more process gases over the substrate to deposit a material on the substrate, the flowing of the one or more process gases over the substrate comprising guiding the one or more process gases through one or more flow paths defined at least in part by a space between the isolation plate and the substrate.

### CROSS-REFERENCE TO RELATED APPLICATIONS

This application claims the benefit of U.S. patent application Ser. No. 18/140,207, filed Apr. 27, 2023, which claims the benefit of provisional patent application Ser. No. 63/441,400, filed Jan. 26, 2023, which is herein incorporated by reference in its entirety.

### BACKGROUND

### Field

The present disclosure relates to semiconductor processing chambers, and more particularly, to one or more methods of and apparatuses for introducing purge gas into a processing chamber.

### Description of the Related Art

Semiconductor substrates are processed for a wide variety of applications, including the fabrication of integrated devices and micro-devices. One method of processing substrates includes depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface. However, the material deposited on the surface of the substrate is often non-uniform in thickness, and therefore, negatively affects the performance of the final manufactured device.

Therefore, a need exists for improved process chamber components and processing methods.

### SUMMARY

The present disclosure relates to a semiconductor processing chamber, and more particularly, to one or more methods of introducing purge gas into a processing chamber.

In one or more embodiments, a method of processing substrates suitable for use in semiconductor manufacturing is provided. The method includes heating a substrate positioned on a substrate support. The method includes flowing a purge gas over an isolation plate disposed above the substrate, the flowing the purge gas including diverting a portion of the purge gas below the isolation plate. The method includes flowing one or more process gases over the substrate to deposit a material on the substrate, the flowing of the one or more process gases over the substrate including guiding the one or more process gases through one or more flow paths defined at least in part by a space between the isolation plate and the substrate.

In one or more embodiments, a method of processing substrates suitable for use in semiconductor manufacturing is provided. The method includes heating a substrate positioned on a substrate support. The method includes flowing a first purge gas over an isolation plate disposed above the substrate. The method includes flowing a second purge gas through one or more perforations in a first parallel block disposed below the isolation plate. The method includes flowing a process gas over the substrate to deposit a material on the substrate, the flowing of the process gas over the substrate including guiding the process gas through a space between the isolation plate and the substrate.

In one or more embodiments, a flow guide applicable for use in semiconductor manufacturing is provided. The flow guide includes an isolation plate having a first face and a second face opposing the first face, the isolation plate having one or more perforations extending through the first face to the second face. The flow guide includes a first parallel block extending from the second face, the first parallel block having a first face approximately perpendicular to the second face of the isolation plate and one or more of perforations extending through the first face of the first parallel block. The method includes a second parallel block extending from the second face, the second parallel block set spaced from the first parallel block to define a flow path between the first parallel block and the second parallel block. The second parallel block has a first face approximately perpendicular to the second face of the isolation plate and one or more of perforations extending through the first face of the second parallel block.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial schematic side cross-sectional view of a processing chamber, according to one or more embodiments.

FIG. 2 is a partial schematic side cross-sectional view of a processing chamber, according to one or more embodiments.

FIG. 3 is a schematic partial perspective view of a flow guide insert, according to one or more embodiments.

FIG. 4 is a partial schematic side cross-sectional view of an isolation plate within a processing chamber, according to one or more embodiments.

FIG. 5 is a partial schematic top cross-sectional view of a processing chamber, according to one or more embodiments.

FIG. 6 is a schematic block diagram view of a method of processing substrates, according to one or more embodiments.

FIG. 7A is a schematic partial perspective view of the liner and parallel blocks of a flow guide insert, according to one or more embodiments.

FIG. 7B is a schematic partial perspective view of the isolation plate of the flow guide insert, according to one or more embodiments.

FIG. 7C is schematic partial perspective view of the isolation plate and the liner of the flow guide insert, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a semiconductor processing chamber, and more particularly, to one or more methods of apparatuses for introducing purge gas within a processing chamber.

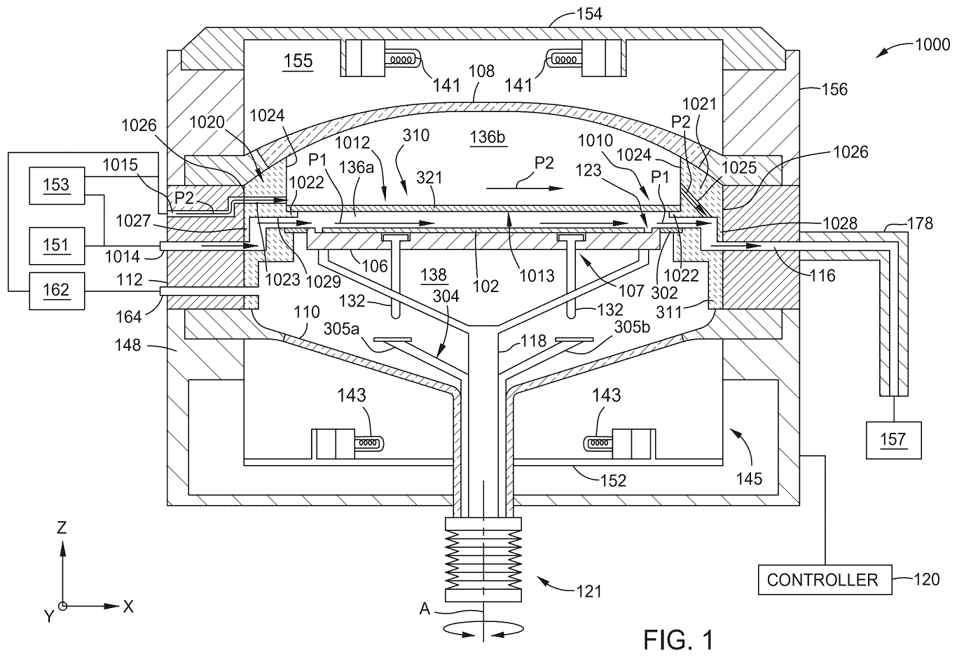

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. The processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. As shown, a controller 120 is in communication with the processing chamber 100 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper window 108 and the lower window 110. The substrate support 106 includes a support face 123 that supports the substrate 102. The plurality of upper heat sources 141 are disposed between the upper window and a lid 154. The plurality of upper heat sources 141 form a portion of the upper heat source module 155. The lid 154 may include a plurality of sensors (not shown) disposed therein or thereon for measuring the temperature within the processing chamber 100. The plurality of lower heat sources 143 are disposed between the lower window 110 and a floor 152. The plurality of lower heat sources 143 form a portion of a lower heat source module 145. In one or more embodiments, the upper window 108 is an upper dome and is formed of an energy transmissive material, such as quartz. In one or more embodiments, the lower window 110 is a lower dome and is formed of an energy transmissive material, such as quartz. A pre-heat ring 302 is disposed outwardly of the substrate support 106. The pre-heat ring 302 is supported on a ledge of the lower liner 311. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

The flow guide insert 1010 includes an isolation plate 321 having a first face 1012 and a second face 1013 opposing the first face 1012. The second face 1013 faces the substrate support 106. The flow guide insert 1010 includes an upper liner 1020. The upper liner 1020 includes an annular section 1021. The upper liner 1020 includes one or more inlet openings 1023 extending to an inner surface 1024 of the annular section 1021 on a first side of the upper liner 1020, and one or more outlet openings 1025 extending to the inner surface 1024 of the annular section 1021 on a second side of the upper liner 1020.

The one or more inlet openings 1023 extend from an outer surface 1026 of the annular section 1021 of the upper liner 1020 to the inner surface 1024. The one or more outlet openings 1025 extend from a lower surface 1029 of the upper liner 1020 to the inner surface 1024. The upper liner 1020 includes a first extension 1027 and a second extension 1028 disposed outwardly of the lower surface 1029 of the upper liner 1020. At least part of the annular section 1021 of the upper liner 1020 is aligned with the first extension 1027 and the second extension 1028. In the embodiment shown in FIG. 1, a lowermost end of the isolation plate 321 is aligned above a lowermost end of the upper liner 1020. In one or more embodiments, as shown in FIG. 1, the lowermost end of the isolation plate 321 is part of the second face 1013, and the lowermost end of the upper liner 1020 is part of the first extension 1027 and/or the second extension 1028. The present disclosure contemplates that the lowermost end of the upper liner 1020 can be part of the lower surface 1029.

The isolation plate 321 is in the shape of a disc, and the annular section 1021 is in the shape of a ring. It is contemplated, however, that the isolation plate 321 and/or the annular section 1021 can be in the shape of a rectangle, or other geometric shapes. The isolation plate 321 at least partially fluidly isolates the upper portion 136b from the lower portion 136a.

The flow module 112 (which can define at least part of one or more sidewalls of the processing chamber 1000) includes one or more first inlet openings 1014 in fluid communication with the lower portion 136a of the processing volume 136. The flow module 112 includes one or more second inlet openings 1015 in fluid communication with the upper portion 136b of the processing volume 136. The one or more first inlet openings 1014 are in fluid communication with one or more flow gaps between the upper liner 1020 and the lower liner 311. The one or more second inlet openings 1015 are in fluid communication with the one or more inlet openings 1023 of the upper liner 1020. The gas inlet(s) 1014 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen and/or chlorine. In one embodiment, which can be combined with other embodiments, the one or more process gases include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

In one or more embodiments, as shown in FIG. 1, the one or more inlet openings 1023 are oriented in a horizontal orientation and the one or more outlet openings 1025 are oriented in an angled orientation. The present disclosure contemplates that the one or more inlet and/or outlet openings 1023, 1025 can be oriented in a horizontal orientation, oriented in an angled (e.g., non-parallel to horizontal) orientation, and/or can include one or more turns (such as the turns shown for the one or more first inlet openings 1014 and the one or more gas exhaust outlets 116).

During a deposition operation (e.g., an epitaxial growth operation), the one or more process gases P1 flow through the one or more first inlet openings 1014, through the one or more gaps, and into the lower portion 136a of the processing volume 136 to flow over the substrate 102. During the deposition operation, one or more purge gases P2 flow through the one or more second inlet openings 1015, through the one or more inlet openings 1023 of the upper liner 1020, and into the upper portion 136b of the processing volume 136. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 1020 and the lower liner 311, and through the one or more gas exhaust outlets 116. The one or more purge gases P2 are exhausted through the one or more outlet openings 1025, through the same gaps between the upper liner 1020 and the lower liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that one or more purge gases can be supplied to the purge volume 138 (through the plurality of purge gas inlets 164) during the deposition operation, and exhausted from the purge volume 138.

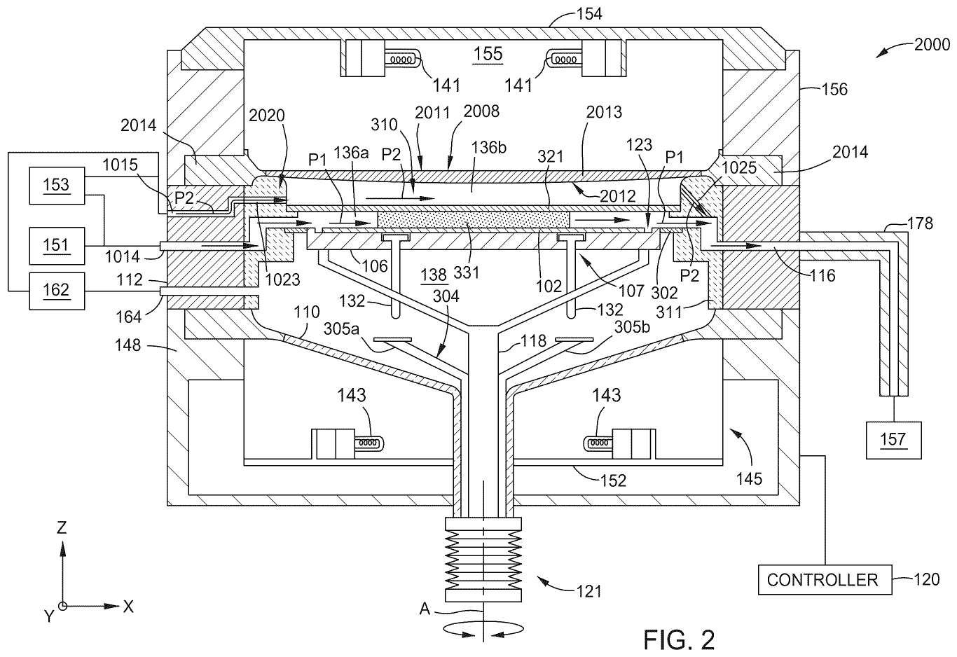

FIG. 2 is a partial schematic side cross-sectional view of a processing chamber 2000, according to one or more embodiments. The processing chamber 2000 is similar to the processing chamber 1000 shown in FIG. 1, and includes one or more of the aspects, features, components, properties, and/or operations thereof. The processing chamber 2000 is shown in a processing condition in FIG. 2.

The processing chamber 2000 includes a window 2008 that at least partially defines the processing volume 136. The window 2008 includes a first face 2011 that is concave or flat (in the embodiment shown in FIG. 2, the first face 2011 is flat). The window 2008 includes a second face 2012 that is convex. The second face 2012 faces the substrate support 106.

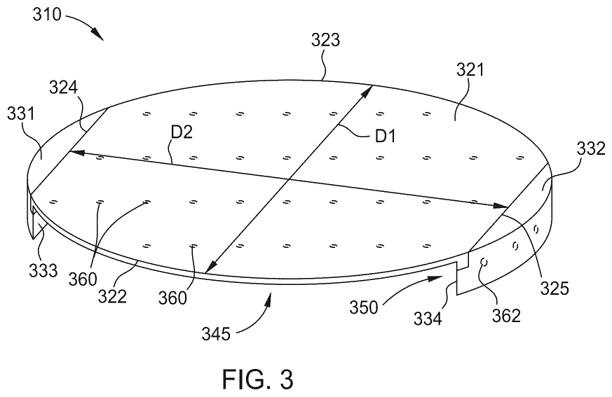

The processing chamber 2000 includes a liner 2020. The liner 2020 is similar to the upper liner 1020 shown in FIG. 1, and includes one or more of the aspects, features, components, properties, and/or operations thereof. The processing chamber 2000 incudes a flow guide insert 310 (shown in FIG. 3), which includes a first parallel block 331, a second parallel block 332, and an isolation plate 321. The parallel block 331 is disposed below an isolation plate 321 and above the substrate support 106. The parallel block 331 assists with flow of process gas P1 over the substrate 102 to facilitate improving deposition uniformity. In one or more embodiments, the flow guide insert 310 is supported by and/or coupled to the upper liner 1020 and/or the pre-heat ring 302. In one or more embodiments, the flow guide insert 310 rests on the upper liner 1020 and/or the pre-heat ring 302.

The window 2008 includes an inner section 2013 and an outer section 2014. The first face 2011 and the second face 2012 are at least part of the inner section 2013. The inner section 2013 is transparent and the outer section 2014 is opaque. The outer section 2014 is received at least partially in one or more sidewalls (such as in the flow module 112 and/or the upper body 156) of the processing chamber 2000.

FIG. 3 is a schematic partial perspective view of the flow guide insert 310, according to one or more embodiments. The flow guide insert 310 includes the isolation plate 321, the first parallel block 331, and the second parallel block 332. The first parallel block 331 and the second parallel block 332 are disposed opposite one another. The flow guide insert 310 has a circular shape, and other geometric configurations are contemplated.

The isolation plate 321 includes a first side 322 and a second side 323 opposing the first side 322 along a first direction D1. Each of the first side 322 and the second side 323 is arcuate. In one or more embodiments, the direction D1 is parallel to the direction of gas flow in the process chambers 1000, 2000 of FIGS. 1 and 2 in order to guide process gas P1 within the rectangular flow opening 350 defined between a planar inner surface 333 of the first parallel block 331 and a planar inner surface 334 of the second parallel block 332.

The first parallel block 331 extends outwardly from and couples to a third side 324 of the isolation plate 321, and the second parallel block 332 extends outwardly from and couples to a fourth side 325 of the isolation plate 321. The third side 324 is opposite the fourth side 325 along a direction D2, which is perpendicular to direction D1. The third side 324 and the fourth side 325 are linear, as are surfaces of the first parallel block 331 and the second parallel block 332 which mate with the third side 324 and the fourth side 325 of the isolation plate 321.

It is contemplated that the first parallel block 331 and the second parallel block 332 may be omitted from the flow guide insert 310 (as shown in FIG. 1). In one or more embodiments where the parallel blocks 331 and 332 are omitted, the isolation plate 321 can be supported by the upper liner 1020 and/or the isolation plate 321 may be secured in the interior of the processing chamber via another attachment mechanism.

It is contemplated that in embodiments with the first and second parallel blocks 331, 332, the size of the parallel blocks may be varied to increase or decrease the lower portion 136a of the processing volume 136. It is also contemplated that the first and second parallel blocks 331, 332 may include actuating supports configured to mechanically move the isolation plate 321 up and down.

During processing, one or more process gases (such as process gas P1 of FIGS. 1 and 2) flow through the rectangular flow opening 350 when flowing through the lower portion 136a and over the substrate 102. The rectangular flow opening 350 facilitates adjustability of process gases, purge gases, and/or cleaning gases (such as pressure and flow rate), to facilitate process uniformity and deposition uniformity while providing a path for cleaning gases to the upper portion 136b. As an example, the rectangular flow opening 350 facilitates using high pressures and low flow rates for the process gases and the cleaning gases. The rectangular flow opening 350 also facilitates mitigation of the effects that rotation of the substrate 102 has on process uniformity and film thickness uniformity during a deposition operation. As an example, the rectangular flow opening mitigates or removes the effects of gas vortex.

In FIG. 3, the isolation plate 321 includes a plurality of perforations 360 formed therethrough. The perforations 360 are sized, spaced (e.g., for hole density) and angled to allow gas (e.g., purge gas P2 of FIGS. 1 and 2) to flow from a top side thereof to a bottom side thereof during processing. It is contemplated that the perforations 360 may be concentrated at the edges or the center of the isolation plate 321, or the perforations may be evenly distributed, or that the perforations 360 may have an increasing size or density along a direction D1 or D2. The perforations 360 may be uniform in size, or the sizes may be non-uniform. In one or more embodiments, the spacing between the perforations 360 may be uniform. In one or more embodiments, the perforations 360 may be clustered in specified areas of the isolation plate 321. In one or more embodiments, the isolation plate 321 may have many small perforations 360 covering the entire plate to keep the isolation plate 321 clean, and the isolation plate 321 may have several larger perforations 360 strategically located to increase deposition uniformity on the substrate 102.

Facing the top of the isolation plate 321, the perforations 360 may be circular, as shown in FIG. 3. It is also contemplated that the perforations 360 may be slits or any other regular or irregular shape, such as in the shape of an elongated slot. Within the isolation plate 321, the perforations 360 may form a right cylinder, an oblique cylinder, a frustum, or any other regular or irregular three-dimensional shape with respect to a plane of the isolation plate 321. It is contemplated that the perforations 360 form right angles with the outer face 345 of the isolation plate 321. It is contemplated that the perforations 360 may tilt towards the process gas P1 flow direction.

During processing, purge gas P2 flows through the perforations of the isolation plate 321 from the upper process region 136b to the lower portion 136a (see FIGS. 1 and 2). The purge gas P2 forms a relatively thin gas curtain along the bottom surface (e.g., the surface facing substrate 102) of the isolation plate. The gas curtain reduces material deposition on the isolation plate 321, extending time between cleaning operations. In addition, the gas curtain allows a substrate to be positioned closed to the isolation plate 321 during processing, thus reducing the processing volume and the amount of processing gas utilized.

The parallel blocks 331, 332 also include a plurality of perforations 362. In one or more embodiments, the perforations 362 may cover the entirety of the inner faces 333, 334 of the parallel blocks 331, 332. In one or more embodiments, the perforations 362 may be concentrated at the edges or the centers of the inner faces 333, 334 of the parallel blocks 331, 332. The perforations 362 may be uniform in size, or the sizes may be non-uniform. In one or more embodiments, the spacing between the perforations 362 may be uniform. In one or more embodiments, the perforations 362 may be clustered in specified areas of the parallel blocks 331, 332.

The perforations 362 are circular, and it is also contemplated that the perforations 362 may be slits or any other regular or irregular shape. Within the parallel blocks 331, 332, the perforations 362 may form a right cylinder, an oblique cylinder, a frustum, or any other regular or irregular three-dimensional shape. The perforations 362 form right angles with the inner faces 333, 334 of the parallel blocks 331, 332. Other orientations (e.g., non-orthogonal) are also contemplated. It is contemplated that the perforations 362 may tilt towards the process gas exhaust 116 or the process gas inlet 1014. The perforations 362 are operatively and fluidly coupled to a gas source for supplying a gas. For example, the perforations 362 may receive a purge gas from the purge gas source 162. The gas provided through the perforations 362 in the direction D2 facilitates improved gas flow along the direction D1. In one or more embodiments, the gas provided through perforations 362 concentrates gas flow of a process gas P1 (see FIGS. 1 and 2) flowing in a direction D1, thus facilitating improving deposition uniformity on a substrate. In one or more embodiments, the gas provided through perforations 362 facilitates flowing process gas P1 nearer to the substrate 102 (see FIGS. 1 and 2), reducing or eliminating diversive flow of the process gas P1, and reducing or eliminating flowing of the process gas P1 up into the upper portion 136b.

Although, in FIG. 3, both the isolation plate 321 and the parallel blocks 331, 332 have perforations 360, 362, it is contemplated that perforations 360, 362 can utilized on only the isolation plate, only the first parallel block 331, only the second parallel block, 332, or any combination thereof.

It is contemplated that the arrangement, size, shape, and other qualities of the perforations 360, 362 may be determined based on modeling and/or experimentation. Additionally, it is to be noted that while perforations 362 are only shown in the second parallel block 332 in FIG. 3 for clarity, perforations 362 are also formed in the first parallel block 331. It is further contemplated that one or more embodiments may not include perforations 360, 362.

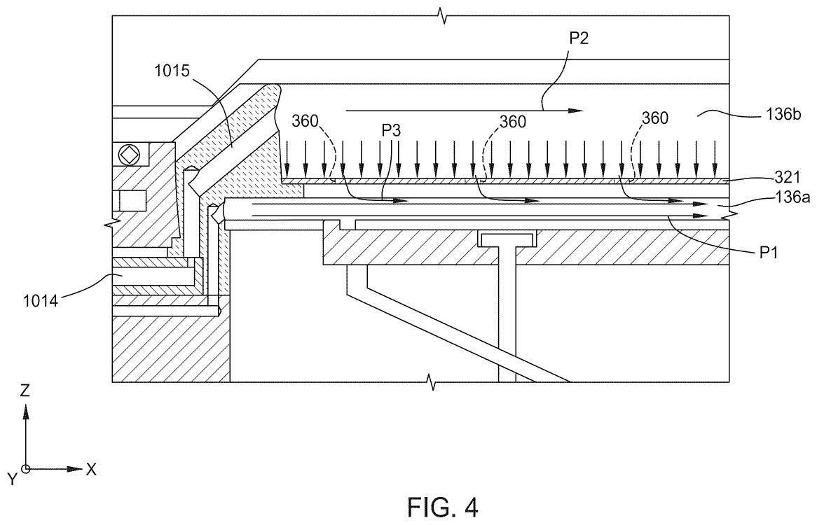

FIG. 4 is a partial schematic side cross-sectional view of an isolation plate 321 within a processing chamber 1000, 2000, according to one or more embodiments. The gas inlet(s) 1014 allow flow of the one or more process gases P1 into the process chamber. The one or more second inlet openings 1015 allow flow of the purge gas P2 into the upper portion 136b of the process chamber. The perforations (shown in FIG. 3) in the isolation plate 321 allow for at least a portion of the purge gas P2 to flow from the upper portion 136b of the process chamber into the lower portion 136a. The flow of the process gas P1 directs the flow of the purge gas P2 towards an exhaust of the process chamber as a flow P3. The flow P3 travels along a lower surface of the isolation plate 321, reducing or preventing deposition of material from the process gas P1 onto the isolation plate 321. The flowrate of the flow P3 is determined in part by the flow rate of the purge gas P2 and the location, number, size, and shape of the perforations 360 in the isolation plate 321.

Without being limited to theory, the flow of the flow P3 reduces the potential for deposition on the isolation plate 321 by forming a gas curtain and or diluting the process gas P1 concentration immediately adjacent the isolation plate 321. The flow of the flow P3 also pushes the process gas flow P1 towards the substrate surface, increasing the gas speed delta between the peak speed and the speed at the substrate surface.

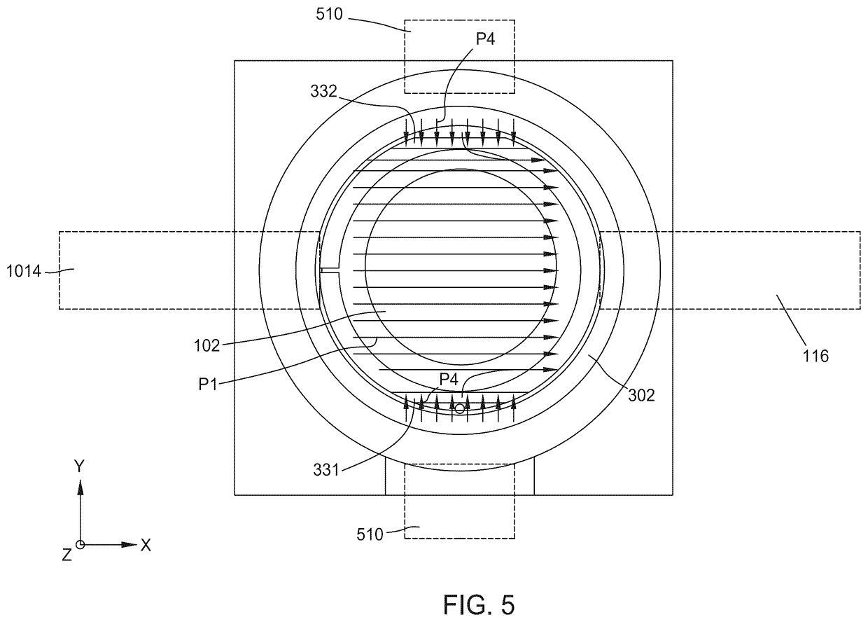

FIG. 5 is a partial schematic top cross-sectional view of a processing chamber 1000, 2000, according to one or more embodiments. In FIG. 5, side purge gas flow P4 is illustrated. Aspects of the side purge gas P4 may be used in combination with aspects of the purge gas flow P3 as shown in FIG. 4.

In FIG. 5, parallel blocks 331, 332 are utilized in the processing chamber 1000 or 2000. As shown in FIG. 3, the parallel blocks 331, 332 have perforations 362 to provide the side purge gas flow P4 into the lower portion 136a of the processing volume 136 (see FIGS. 1 and 2). The parallel blocks 331, 332 are connected to a side purge gas inlet 510, and the side purge gas inlet 510 may be connected to the purge gas source 162. It is contemplated that one or more embodiments may only contain one parallel block 331, 332 with perforations 362, and the other parallel block 331, 332 can be unperforated.

The process gas P1 flows from the first inlet opening 1014 into the lower portion 136a of the processing volume 136 and over the substrate 102. The side purge gas flow P4 combines with the process gas P1 in the lower portion 136a of the processing volume 136. The side purge gas flow P4 is introduced into the lower portion 136a perpendicular to the flow of the process gas P1. The side purge gas flow P4 concentrates the flow of process gas P1 over the substrate 102, thus facilitating improving deposition uniformity on the substrate 102 and reducing deposition of material on internal surfaces of the processing chamber 100. The combined flow of the process gas P1 and the side purge gas flow P4 exit through the gas exhaust outlets 116.

The flow rate of the side purge gas flow P4 may be determined based on modeling and/or experimental studies. It is contemplated that the side purge gas flow P4 may range from 1 L/s to 20 L/s.

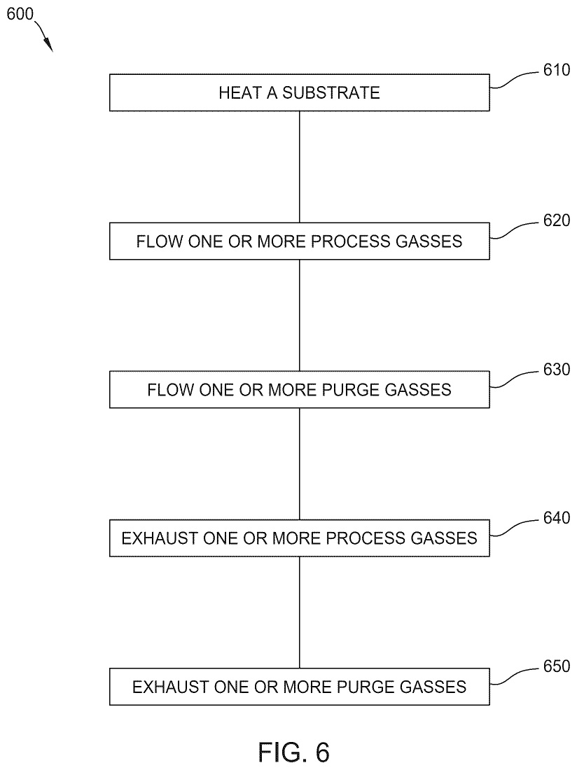

FIG. 6 is a schematic block diagram view of a method 600 of processing substrates 102, according to one or more embodiments.

Operation 610 includes heating a substrate positioned on a substrate support. In one more embodiments, the substrate is heated using heat sources and the substrate support is a pedestal, such as a susceptor which absorbs radiation from the heat sources and transfers thermal energy to the substrate. In one or more embodiments, the substrate support includes one or more ring segments.

Operation 620 includes flowing one or more process gases over the substrate to form one or more layers on the substrate. The flowing of the one or more process gases over the substrate includes guiding the one or more process gases through a rectangular flow opening of a flow guide insert. In one or more embodiments, the one or more process gases are supplied at a pressure that is 300 Torr or greater, such as within a range of 300 Torr to 600 Torr, or greater. In one or more embodiments, the one or more process gases are supplied at a flow rate that is less than 5,000 standard cubic centimeters per minute (SCCM). In one or more embodiments, the substrate is rotated at a rotation speed that is less than 8 rotations-per-minute (RPM) during the flowing of the one or more process gases over the substrate. In one or more embodiments, the rotation speed is 1 RPM. The one or more purge gases can flow into the processing chamber before, during, and/or after one or more of operation 610, operation 630, operation 640, and/or operation 650.

Operation 630 includes flowing one or more purge gases into the processing chamber. The one or more purge gases can flow into the processing chamber before, during, and/or after one or more of operation 610, operation 620, operation 640, and/or operation 650. The one or more purge gases can flow from perforations in the isolation plate or perforations in the parallel blocks, as described above. In one or more embodiments, operation 630 includes simultaneous flow of purge gas from the isolation plate and the parallel blocks for the entirety of operation 630. In one or more embodiments, operation 630 includes introducing purge gas into the lower portion of the processing area only from the isolation plate or the parallel blocks. In one or more embodiments, operation 630 includes flow of purge gas from the isolation plate and the parallel blocks for portions of operation 630.

While flowing the one or more process gases in operation 620 and the one or more purge gases in operation 630, the one or more process gases are thermally decomposed to form an epitaxial layer on an upper surface of a substrate.

Operation 640 includes exhausting the one or more process gases. Operation 640 may occur before, during, and/or after one or more of operation 620, operation 630, and/or operation 650.

Operation 650 includes exhausting the one or more purge gases. Operation 650 may occur before, during, and/or after one or more of operation 610, operation 620, operation 630, and/or operation 640.

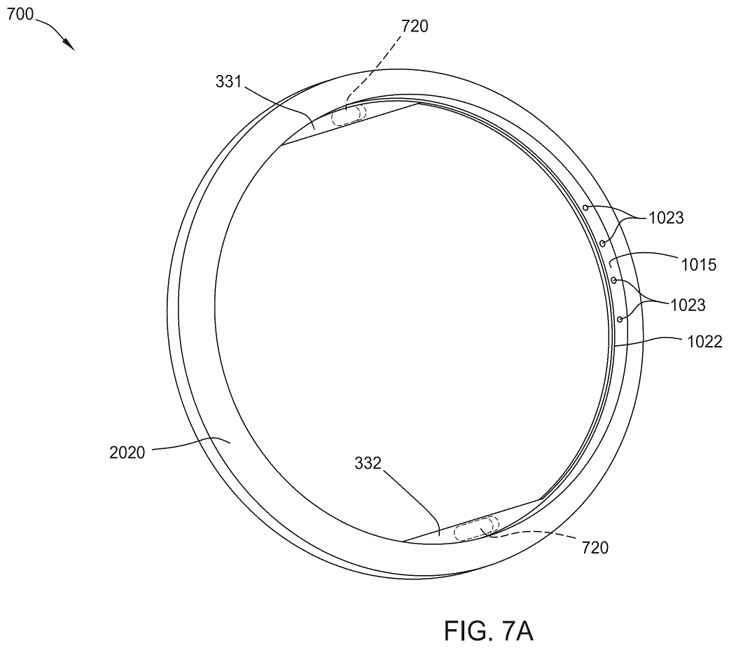

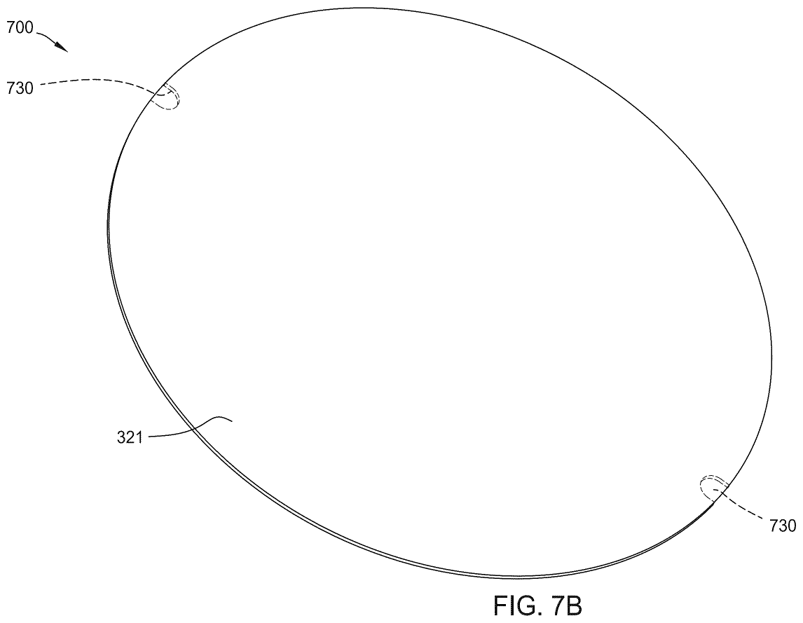

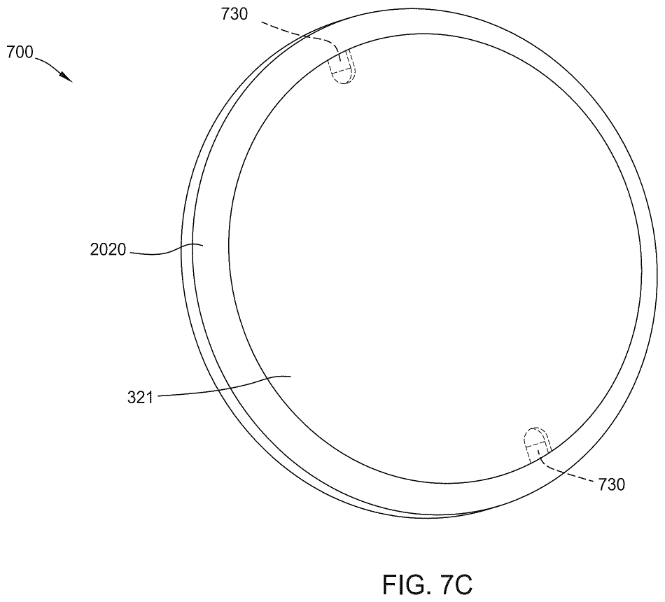

FIGS. 7A-7B are schematic partial perspective views of elements of a flow guide insert 700, according to one or more embodiments.

FIG. 7A is a schematic partial perspective view of the liner 2020 and parallel blocks 331, 332 of the flow guide insert 700, according to one or more embodiments. In one or more embodiments, the parallel blocks 331, 332 and the liner 2020 may be manufactured together as a single integral part of the processing chamber 2000 such that the parallel blocks 331, 332 and the liner 2020 are part of the same opaque body. In one or more embodiments, the parallel blocks 331, 332 are manufactured as separate bodies from the liner 2020, and the parallel blocks 331, 332 are fused to the liner 2020 in a fusing operation. In one or more embodiments, the parallel blocks 331, 332 are welded to the liner 2020.

As shown in FIG. 7A, in one or more embodiments, the parallel blocks 331, 332 includes optional slots 720. It is contemplated that the slots 720 may be omitted from the parallel blocks 331, 332.

FIG. 7B is a schematic partial perspective view of the isolation plate 321 of the flow guide insert 700, according to one or more embodiments. In one or more embodiments, the isolation plate 321 includes notches 730. It is contemplated that the notches 730 may be omitted from the isolation plate 321. In one or more embodiments, the notches 730 of the isolation plate 321 and the slots 720 of the parallel blocks 331, 332 are used to position the isolation plate 321 on the parallel blocks 331, 332 and one or more inner ledges 1022 of the liner 2020. For example, transfer equipment (such as heads of lift pins) can extend through the notches 730 and into slots 720 when the isolation plate 321 is lowered onto the liner 1020.

FIG. 7C is schematic partial perspective view of the isolation plate 321 and the liner 2020 of the flow guide insert 700, according to one or more embodiments. In one or more embodiments, the notches 730 vertically align with the slots 720 when the isolation plate 321 is positioned on the parallel blocks 331, 332 and/or the one or more inner ledges 1022, and/or when the isolation plate 321 is fused to the parallel blocks 331, 332 and/or the one or more inner ledges 1022.

In one or more embodiments, the isolation plate 321 is fused to the parallel blocks 331, 332 and/or the one or more inner ledges 1022. In one or more embodiments, the parallel blocks 331, 332 are manufactured as separate bodies from the isolation plate 321, and the parallel blocks 331, 332 (and.or the one or more inner ledges 1022) are fused to the isolation plate 321 in a fusing operation. In one or more embodiments, the parallel blocks 331, 332 and/or the one or more inner ledges 1022 are welded to the isolation plate 321.

A welding process (e.g., for the fusing) may include the operations of utilizing a welding rod of the same type of material (e.g., an opaque material) as the liner 2020 (e.g., the one or more inner ledges 1022), the parallel blocks 331, 332, and/or the isolation plate 321. In one or more embodiments, the welding rod has a diameter that is less than 5.0 mm, such as within a range of 2.0 mm to 3.0 mm. In one or more embodiments, the isolation plate 321 is formed of a transparent material (such as transparent quartz), and the liner 2020 and the parallel blocks 331, 332 are formed of an opaque material (such as white quartz, black quartz, silicon carbide (SiC), quartz with impregnated particles such as SiC or Si, and/or graphite coated with SiC). The welding rod material may include the opaque material to be the same type of material as the parallel blocks 331, 332 and the liner 2020. The welding rod can be positioned adjacent to the isolation plate 321 in an arcuate pattern (such as a circular pattern). In one or more embodiments, a hydrogen-oxygen (H—O) torch may be utilized in the welding process to melt the welding rod. The welding may be conducted at a temperature within a range of 1900° C. to 2000° C. In one or more embodiments, the resulting weld may be ground down, acid washed, and/or flame polished to remove lumps or nodules for a smoother weld seam.

Benefits of the present disclosure include reduced diversive flow of process gases; enhanced deposition thicknesses; enhanced deposition uniformities; reduced coating of chamber components (such as the isolation plate 321); reduced cleaning; increased throughput and efficiency; and reduced chamber downtime.

It is contemplated that one or more aspects disclosed herein may be combined. As an example, one or more aspects, features, components, operations and/or properties of the processing chamber 1000, the processing chamber 2000, the flow guide insert 310, the method 600, and/or the flow guide insert 700 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A flow guide applicable for use in semiconductor manufacturing, the flow guide comprising:
an isolation plate having a first face and a second face opposing the first face, the isolation plate having one or more perforations extending through the first face to the second face;
a first parallel block extending from the second face, the first parallel block having a first face approximately perpendicular to the second face of the isolation plate and one or more perforations extending through the first face of the first parallel block; and
a second parallel block extending from the second face, the second parallel block set spaced from the first parallel block to define a flow path between the first parallel block and the second parallel block, the second parallel block having a first face approximately perpendicular to the second face of the isolation plate and one or more of perforations extending through the first face of the second parallel block.

2. The flow guide of claim 1, wherein the one or more perforations extending through the first face to the second face are evenly distributed on the isolation plate.

3. The flow guide of claim 1, wherein the one or more perforations extending through the first face to the second face comprise a first plurality of perforations having a first diameter and a second plurality of perforations having a second diameter, wherein the first diameter is smaller than the second diameter.

4. The flow guide of claim 3, wherein the first parallel block and the second parallel block are fused to the isolation plate.

5. The flow guide of claim 4, wherein the first parallel block and the second parallel block are integrally formed with a liner.

6. The flow guide of claim 1, wherein the isolation plate is formed of a transparent material and wherein the first parallel block and the second parallel block are formed of an opaque material.

7. The flow guide of claim 6, wherein the transparent material comprises a transparent quartz.

8. The flow guide of claim 6, wherein the opaque material comprises at least one of white quartz, black quartz, silicon carbide (SiC), quartz with impregnated particles such as SiC or Si, or graphite coated with SiC.

9. A processing chamber comprising:
a chamber body;
an upper window and a lower window disposed within the chamber body, the upper window and the lower window at least partially defining a processing volume;
a substrate support disposed within the processing volume; and
an isolation plate disposed within the processing volume, the isolation plate having a first face and a second face opposing the first face, the isolation plate having one or more perforations extending through the first face to the second face, the isolation plate at least partially fluidly isolating an upper portion of the processing volume from a lower portion of the processing volume.

10. The processing chamber of claim 9, further comprising:
a first parallel block extending from the second face of the isolation plate, the first parallel block having a first face approximately perpendicular to the second face of the isolation plate; and
a second parallel block extending from the second face of the isolation plate, the second parallel block set spaced from the first parallel block to define a flow path between the first parallel block and the second parallel block, the second parallel block having a first face approximately perpendicular to the second face of the isolation plate.

11. The processing chamber of claim 10, wherein the first parallel block further comprises one or more perforations extending through the first face of the first parallel block.

12. The processing chamber of claim 10, wherein the second parallel block further comprises one or more perforations extending through the first face of the second parallel block.

13. The processing chamber of claim 9, wherein the one or more perforations extending through the first face to the second face are evenly distributed on the isolation plate.

14. The processing chamber of claim 9, wherein the one or more perforations extending through the first face to the second face comprise a first plurality of perforations having a first diameter and a second plurality of perforations having a second diameter, wherein the first diameter is smaller than the second diameter.

15. The processing chamber of claim 10, wherein the first parallel block and the second parallel block are fused to the isolation plate.

16. The processing chamber of claim 10, wherein the first parallel block and the second parallel block are integrally formed with a liner.

17. A flow guide applicable for use in semiconductor manufacturing, the flow guide comprising:
an isolation plate having a first face and a second face opposing the first face, the isolation plate having one or more perforations extending through the first face to the second face, the isolation plate comprising a transparent material;
a first parallel block extending from the second face, the first parallel block having a first face approximately perpendicular to the second face of the isolation plate; and
a second parallel block extending from the second face, the second parallel block set spaced from the first parallel block to define a flow path between the first parallel block and the second parallel block, the second parallel block having a first face approximately perpendicular to the second face of the isolation plate, the first parallel block and the second parallel block comprising an opaque material.

18. The flow guide of claim 17, wherein:
the first parallel block further comprises one or more perforations extending through the first face of the first parallel block; and
the second parallel block further comprises one or more perforations extending through the first face of the second parallel block.

19. The flow guide of claim 17, wherein the first parallel block and the second parallel block are fused to the isolation plate.

20. The flow guide of claim 17, wherein the first parallel block and the second parallel block are integrally formed with a liner.
